(19) United States
(12) Patent Application Publication
(10) Pub. No.: US 2012/0237858 A1
(43) Pub. Date: Sep. 20, 2012

(54) PHOTOMASK AND A METHOD FOR DETERMINING A PATTERN OF A PHOTOMASK

(75) Inventor: Chun Wei Wu, Taishan Township (TW)

(73) Assignee: NANYA TECHNOLOGY CORPORATION, Kueishan (TW)

(21) Appl. No.: 13/051,339

(22) Filed: Mar. 18, 2011

(51) Int. Cl. G03F 1/00; G06F 17/50

(52) U.S. Cl. 430/5; 716/54

(57) ABSTRACT

The present invention relates to a photomask and a method for determining a pattern of the photomask. The photomask includes a base and a plurality of square areas, wherein the light transmittancy of the square areas is different from that of the base. The square areas are arranged on the base with an array arrangement, and the gaps between adjacent square areas are not even. Whereby, the photomask has better normalized image log-slope (NILS) or depth of focus (DOF).

### 1. TECHNICAL FIELD

The present invention generally relates to a photomask and a method for determining a pattern of the photomask, and more particularly, to a photomask for preparing circular patterns in an array features and a method for determining a pattern of the photomask.

### 2. BACKGROUND

In a semiconductor memory device such as dynamic random access memory (DRAM) devices having a plurality of memory cells each consisting of one access transistor and one storage capacitor, an increase in cell density inevitably demands a reduction in the size of the transistor and the capacitor in order to prevent an increase in memory chip size. Higher integration densities correlate to smaller sizes of semiconductor device. Therefore, there is a demand for an advanced technique for forming a contact between conductive layers in order to ensure operation of the semiconductor memory device. As designs for integrated circuit devices are reduced to sub-50 nm scale, the critical dimension for memory transistors or memory array face lithography limitations for form contacts.

FIG. 1 shows a first conventional preliminary designed pattern for a photomask. The first preliminary designed pattern 1 is used to produce a corresponding pattern on a photomask. The first preliminary designed pattern 1 comprises a basic portion 11 and a plurality of square portions 12, wherein the square portions 12 correspond to light transmissive area of the photomask and the basic portion 11 corresponds to opaque area of the photomask. The square portions 12 are arranged on the basic portion 11 with a chessboard arrangement. The square portions 12 the same sizes, and each of the square portions 12 has four edges 121 and a width W. The distance between the corresponding positions of two adjacent square portions 12 is defined as a pitch P. Each of the edges 121 of each of the square portions 12 faces one edge of adjacent square portion 12. That is, each of the square portions 12 faces its adjacent square portion by edge to edge, and the gaps G₁ between adjacent square portions 12 are even.

FIG. 2 shows a second conventional preliminary designed pattern for a photomask. In order to find better normalized image log-slope (NILS) or depth of focus (DOF), global bias B₁ is applied to the first preliminary designed pattern 1 to form the second preliminary designed pattern 2. The second preliminary designed pattern 2 comprises a basic portion 21 and a plurality of square portions 22. Each of the square portions 22 is an enlarged square portion 12, and has a width W₁, wherein W₁=W+2B₁, and W₁<P.

FIG. 3 shows a third conventional preliminary designed pattern for a photomask. Global bias B₂ (B₂>B₁) is applied to the first preliminary designed pattern 1 to form the third preliminary designed pattern 3. The third preliminary designed pattern 3 comprises a plurality of square portions 32. Each of the square portions 32 is an enlarged square portion 12, and has a width W₂, wherein W₂=W+2B₂=P. As shown in the figure, since W₂=P, there is no basic portion in the third preliminary designed pattern 3. Therefore, the feature of the pattern is disappeared, and the third preliminary designed pattern 3 cannot be used to produce a corresponding pattern on a photomask. As stated above, the global bias tolerance is constrained by the pitch P. That is, when W₂ equal to P, global bias cannot be added anymore.

### SUMMARY

The present invention is directed to a photomask for preparing circular patterns in an array features. The photomask comprises a base and a plurality of square areas, wherein the light transmittancy of the square areas is different from that of the base. The square areas are arranged on the base with an array arrangement, and the gaps between adjacent square areas are not even.

The present invention is also directed to a photomask for preparing circular patterns in an array features. The photomask comprises a base and a plurality of square areas, wherein the light transmittancy of the square areas is different from that of the base. The square areas are arranged on the base with an array arrangement, the photomask has a longitudinal axis, each of the square areas has four edges, and an inclination angle is between one edge of each of the square areas and the longitudinal axis.

The present invention is also directed to a method for determining a pattern of a photomask. The method comprises the following steps of: (a) providing a preliminary designed pattern, the preliminary designed pattern comprising a basic portion and a plurality of square portions, wherein the square portions are arranged on the basic portion with an array arrangement, and the gaps between adjacent square portions are not even; and (b) producing the pattern of the photomask according to the preliminary designed pattern.

The present invention is also directed to a method for determining a pattern of photomask. The method comprises the following steps of: (a) providing a preliminary designed pattern, the preliminary designed pattern comprising a basic portion, a plurality of square portions and a longitudinal axis, wherein the square portions are arranged on the basic portion with an array arrangement, each of the square portions has four edges, and an inclination angle is between one edge of each of the square portions and the longitudinal axis; and (b) producing the pattern of the photomask according to the preliminary designed pattern.

In the present invention, better normalized image log-slope (NILS) or depth of focus (DOF) can be found, and larger global bias can be applied.

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a first conventional preliminary designed pattern for a photomask;

FIG. 2 is a second conventional preliminary designed pattern for a photomask;

FIG. 3 is a third conventional preliminary designed pattern for a photomask;

FIG. 4 is a first preliminary designed pattern for a photomask according to an embodiment of the present invention;

FIG. 5 is a pattern of a photomask according to the first preliminary designed pattern of FIG. 4;

FIG. 6 is a second preliminary designed pattern for a photomask according to another embodiment of the present invention;

FIG. 7 is an enlarged portion of FIG. 6;

FIG. 8 is a pattern of a photomask according to the second preliminary designed pattern of FIG. 6;

FIG. 9 is a third preliminary designed pattern for a photomask according to another embodiment of the present invention;

FIG. 10 is a fourth preliminary designed pattern for a photomask according to another embodiment of the present invention; and

FIG. 11 is a pattern of a photomask according to the fourth preliminary designed pattern of FIG. 10.

### DETAILED DESCRIPTION

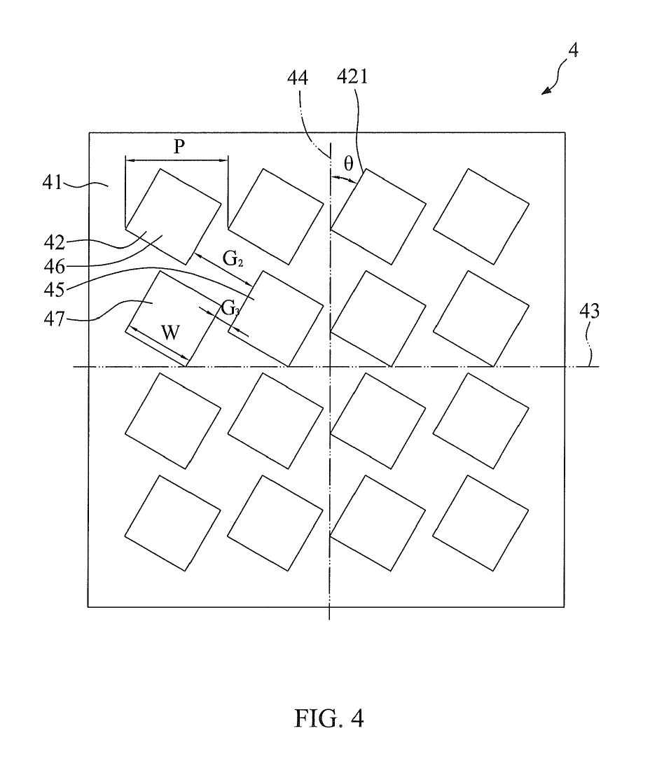

FIG. 4 shows a first preliminary designed pattern for a photomask according to an embodiment of the present invention. The first preliminary designed pattern 4 is used to produce a corresponding pattern on a photomask. The first preliminary designed pattern 4 comprises a basic portion 41, a plurality of square portions 42, a traverse axis 43 and a longitudinal axis 44. The square portions 42 correspond to light transmissive area of the photomask and the basic portion 41 corresponds to opaque area of the photomask. The traverse axis 43 is perpendicular to the longitudinal axis 44.

The square portions 42 are arranged on the basic portion 41 with an array arrangement. The square portions 42 have the same sizes, and each of the square portions 42 has four edges 421 and a width W. The distance between the corresponding positions of two adjacent square portions 42 is defined as a pitch P.

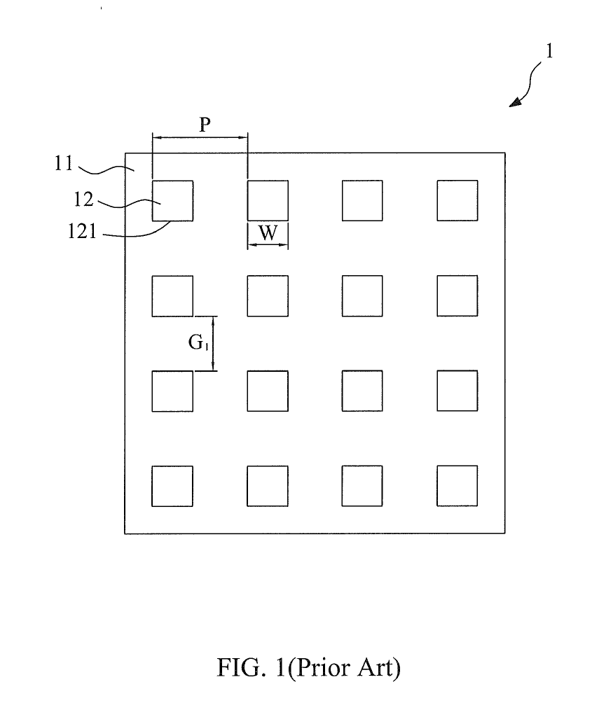

In this embodiment, the width W and the pitch P are equal to the width W and the pitch P of FIG. 1, respectively. Compared with the square portions 12 of FIG. 1, the square portions 42 are rotated clockwise with an angle of θ degrees, wherein θ is greater than 0 degree and less than 45 degrees. Therefore, an inclination angle θ is between one edge 421 and the longitudinal axis 44.

In this embodiment, each of the edges 421 of each of the square portions 42 faces two edges of two square portions, and the gaps are not equal. For example, the preliminary designed pattern 4 comprises a first square portion 45, a second square portion 46 and a third square portion 47. A first gap G₂ is between the first square portion 45 and the second square portion 46, and a second gap G₃ is between the first square portion 45 and the third square portion 47. The first gap G₂ is different from the second gap G₃, i.e., the first gap G₂ is not equal to the second gap G₃. Therefore, the gaps between adjacent square portions 42 are not even. It is to be noted that the square portions 42 are not arranged on the basic portion 41 with a chessboard arrangement.

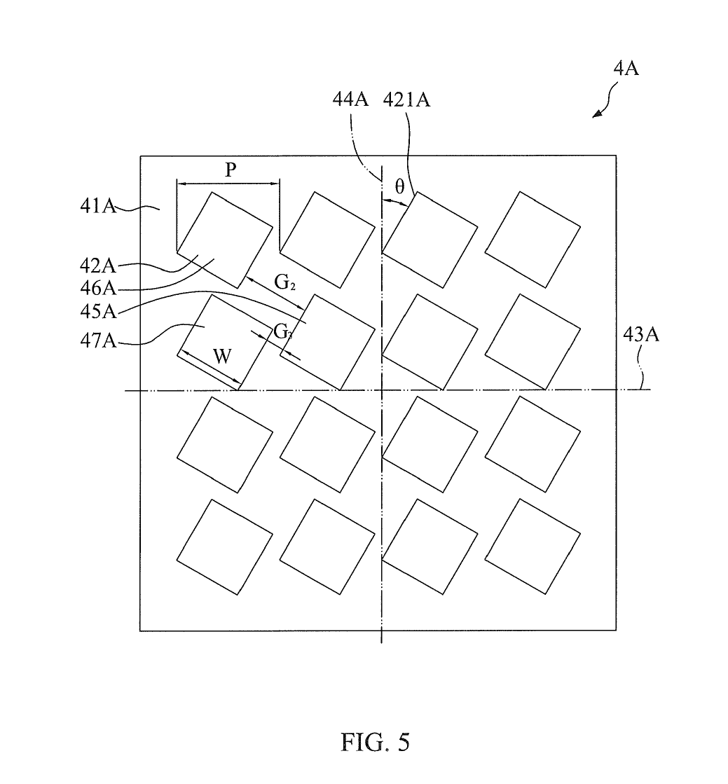

FIG. 5 shows a pattern of a photomask according to the first preliminary designed pattern of FIG. 4. The pattern of the photomask is made by the following steps. First, a preliminary designed pattern is provided. Then, the pattern of the photomask is produced according to the preliminary designed pattern. In this embodiment, the preliminary designed pattern is the first preliminary designed pattern 4 of FIG. 4. Therefore, the pattern of the photomask 4A corresponds to the first preliminary designed pattern 4 of FIG. 4. The photomask 4A is used for preparing circular patterns in an array features, and comprises a base 41A, a plurality of square areas 42A, a traverse axis 43A and a longitudinal axis 44A. The light transmittancy of the square areas 42A is different from that of the base 41A. In this embodiment, the square areas 42A are light transmissive, and the base 41A is opaque. The traverse axis 43A is perpendicular to the longitudinal axis 44A.

The square areas 42A are arranged on the base 41A with an array arrangement, and the gaps between adjacent square areas 42A are not even. The square areas 42A have the same sizes, and each of the square areas 42A has four edges 421A and a width W. An inclination angle θ is between one edge 421A and the longitudinal axis 44A. In this embodiment, each of the edges 421A of each of the square areas 42A faces two edges of two square areas, and the gaps are not equal. For example, the photomask 4A comprises a first square area 45A, a second square area 46A and a third square area 47A. The first gap G₂ is between the first square area 45A and the second square area 46A, and the second gap G₃ is between the first square area 45A and the third square area 47A. The first gap G₂ is different from the second gap G₃, i.e., the first gap G₂ is not equal to the second gap G₃. Therefore, the gaps between adjacent square areas 42A are not even.

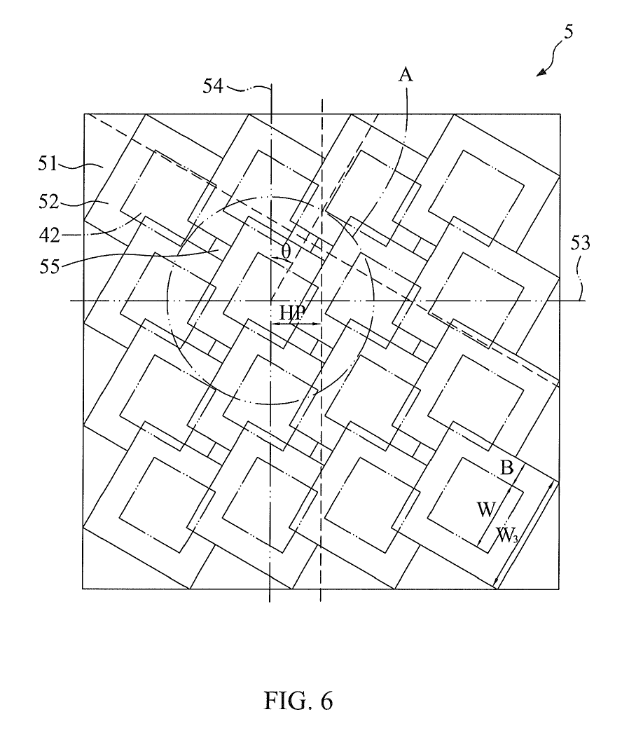

FIG. 6 shows a second preliminary designed pattern for a photomask according to another embodiment of the present invention. In order to find better normalized image log-slope (NILS) or depth of focus (DOF), global bias B is applied to the first preliminary designed pattern 4 to form the second preliminary designed pattern 5. The second preliminary designed pattern 5 comprises a basic portion 51 and a plurality of enlarged square portions 52. Each of the enlarged square portions 52 is enlarged from the square portion 42, and has a width W₃, wherein W₃=W+2B. Four enlarged square portions 52 enclose to form an enclosed portion 55.

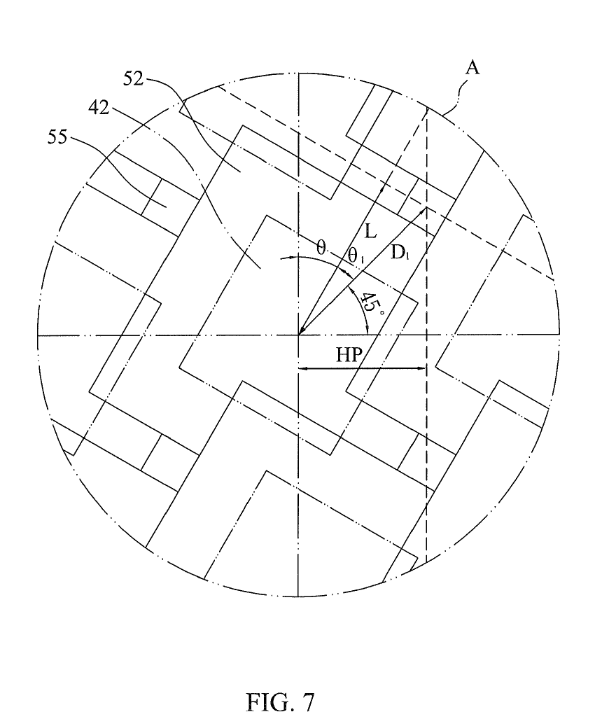

FIG. 7 shows an enlarged portion A of FIG. 6. As shown in FIG. 7, the following equations are obtained according geometric relationship.

D1=HP×sec45°, wherein HP=P/2

θ₁=90°−45°−θ=45°−θ

L=D1×cos θ₁=P/2×sec45°×cos(45°−θ)=\sqrt{2} P/2×cos(45°−θ)

Maximum of W₃ is 2L, which means when W₃ is extended to 2L, the feature of pattern will disappear. Therefore, when θ=0°, W₃=2L=P; when θ=45°, W₃=2L=\sqrt{2} P. Since 0°<θ<45°, P<W₃<\sqrt{2} P. As a result, the maximum of the width W₃ of the enlarged square portion 52 can reach to \sqrt{2} P, which means the mask bias tolerance is beyond the pitch constraint.

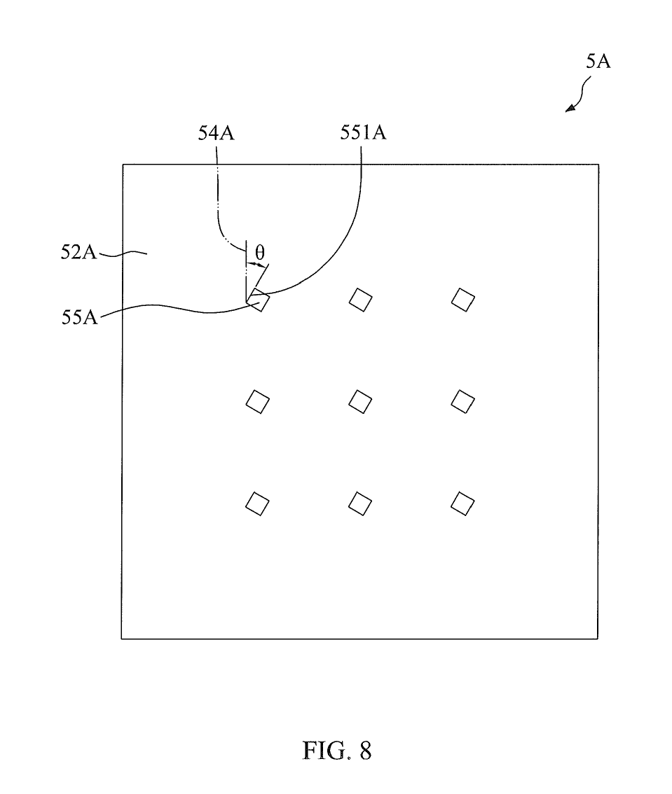

FIG. 8 shows a pattern of a photomask according to the second preliminary designed pattern of FIG. 6. The pattern of the photomask is made by the following steps. First, a preliminary designed pattern is provided. The preliminary designed pattern has a plurality of square portions. Then, the preliminary designed pattern is adjusted by applying global bias to enlarge the square portions to become enlarged square portions. Then, the pattern of the photomask is produced according to the preliminary designed pattern. In this embodiment, the preliminary designed pattern is the first preliminary designed pattern 4 of FIG. 4 and then is adjusted to become the second preliminary designed pattern 5 of FIG. 6. Therefore, the pattern of the photomask 5A corresponds to the second preliminary designed pattern 5 of FIG. 6.

The photomask 5A is used for preparing circular patterns in an array features, and comprises a base 52A and a plurality of square areas 55A. The base 52A corresponds to the enlarged square portions 52, and the square areas 55A correspond to the enclosed portions 55. The light transmittancy of the square areas 55A is different from that of the base 52A. In this embodiment, the square areas 55A are light transmissive, and the base 52A is opaque. The square areas 55A are arranged on the base 52A with an array arrangement, and the gaps between adjacent square areas 55A are not even. The square areas 55A have the same sizes, and each of the square areas 55A has four edges 551A. An inclination angle θ is between one edge 551A and the longitudinal axis 54A.

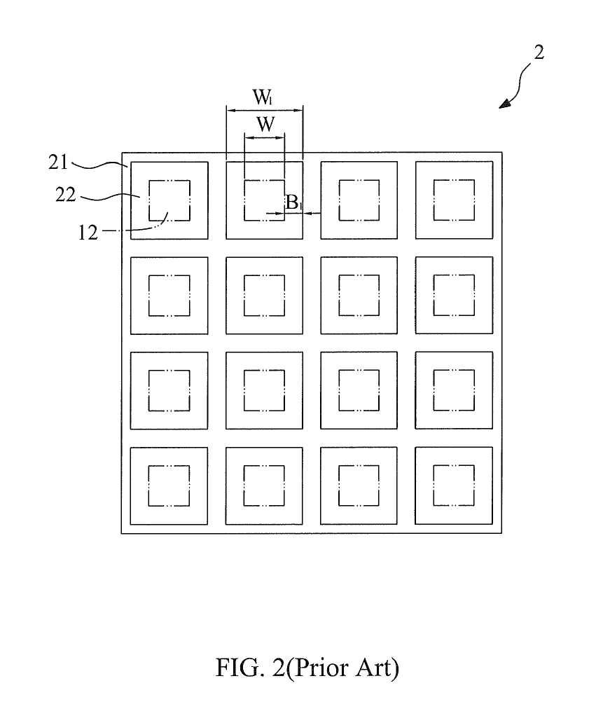

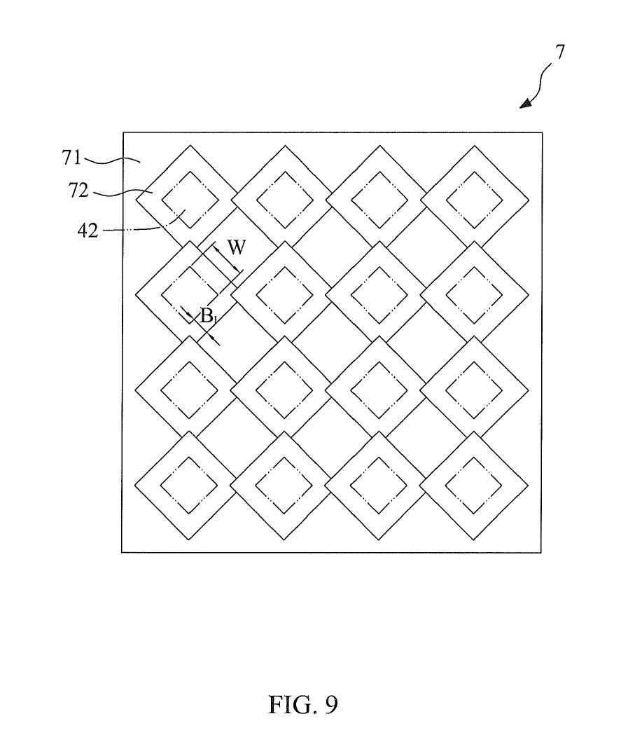

FIG. 9 shows a third preliminary designed pattern for a photomask according to another embodiment of the present invention. The third preliminary designed pattern 7 is adjusted from the first preliminary designed pattern 4 of FIG. 4 when the inclination angle θ is 45 degrees and global bias B₁ is applied. The third preliminary designed pattern 7 comprises a basic portion 71 and a plurality of enlarged square portions 72. The global bias B₁ is equal to the global bias B₁ of FIG. 2. In this embodiment, the enlarged square portions 72 are in diamond shapes, and each of the enlarged square portions 72 faces its adjacent enlarged square portions by corner to corner.

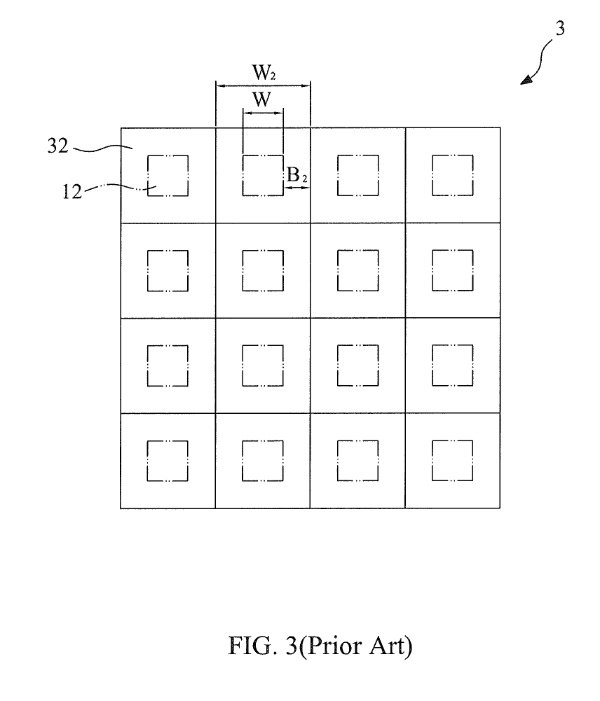

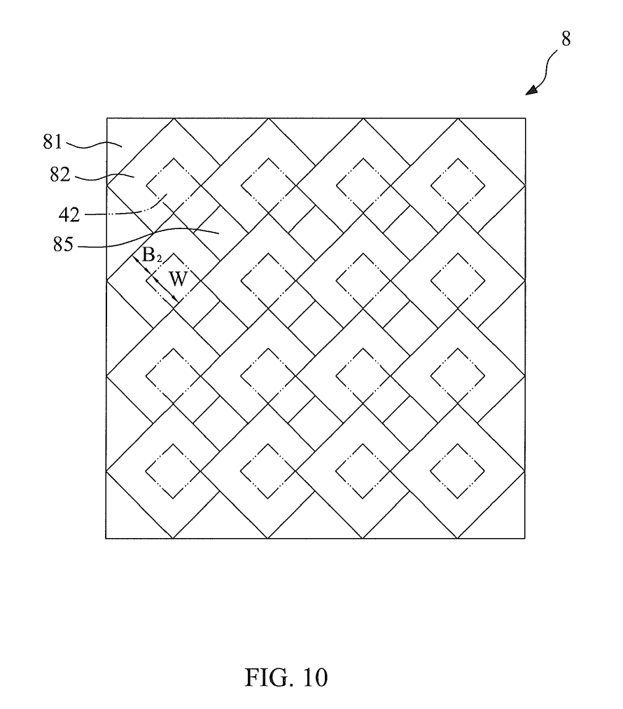

FIG. 10 shows a fourth preliminary designed pattern for a photomask according to another embodiment of the present invention. The fourth preliminary designed pattern 8 is adjusted from the first preliminary designed pattern 4 of FIG. 4 when the inclination angle θ is 45 degrees and global bias B₂ is applied. The fourth preliminary designed pattern 8 comprises a basic portion 81 and a plurality of enlarged square portions 82. The global bias B₂ is equal to the global bias B₂ of FIG. 3. Four enlarged square portions 82 enclose to form an enclosed portion 85. Therefore, the enclosed portions 85 serve as the feature of the pattern. As stated above, the third conventional preliminary designed pattern 3 (FIG. 3) cannot be used to produce a corresponding pattern on a photomask, however, the fourth preliminary designed pattern 8 can be used to produce a corresponding pattern on a photomask.

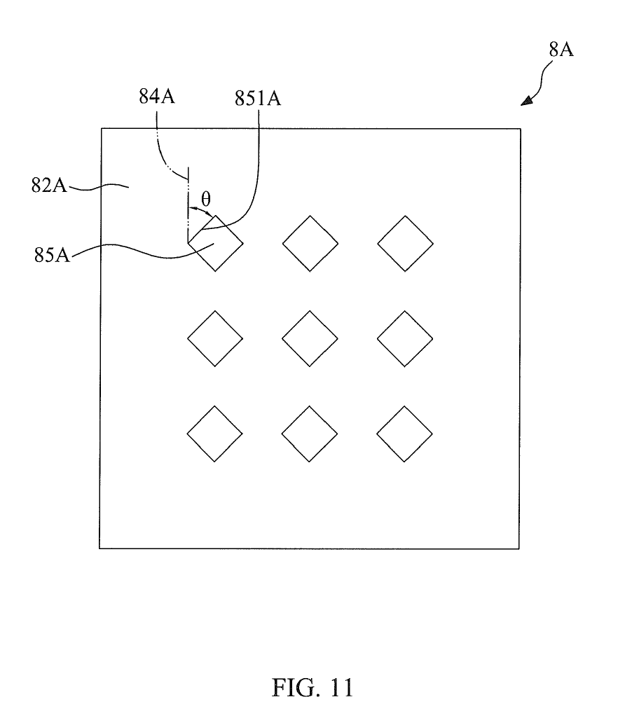

FIG. 11 shows a pattern of a photomask according to the fourth preliminary designed pattern of FIG. 10. The pattern of the photomask 8A corresponds to the fourth preliminary designed pattern 8 of FIG. 10. The photomask 8A is used for preparing circular patterns in an array features, and comprises a base 82A and a plurality of square areas 85A. The base 82A corresponds to the enlarged square portions 82, and the square areas 85A correspond to the enclosed portions 85. The light transmittancy of the square areas 85A is different from that of the base 82A. In this embodiment, the square areas 85A are light transmissive, and the base 82A is opaque. The square areas 85A are arranged on the base 82A with an array arrangement, and the gaps between adjacent square areas 85A are not even. The square areas 85A have the same sizes, and each of the square areas 85A has four edges 851A. An inclination angle θ of 45 degrees is between one edge 851A and the longitudinal axis 84A. In this embodiment, the square areas 85A are in diamond shapes, and each of the square areas 85A faces its adjacent square areas by corner to corner.

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A photomask for preparing circular patterns in an array features, comprising a base and a plurality of square areas, wherein the light transmittancy of the square areas is different from that of the base, the square areas are arranged on the base with an array arrangement, the photomask comprises a first square area, a second square area and a third square area, a first gap is between the first square area and the second square area, a second gap is between the first square area and the third square area, and the first gap is different from the second gap.

2. The photomask of claim 1, wherein the square areas have the same sizes.

3. The photomask of claim 1, wherein the square areas are in diamond shapes, and each of the square areas faces its adjacent square areas by corner to corner.

4. The photomask of claim 1, wherein the square areas are light transmissive, and the base is opaque.

5. A photomask for preparing circular patterns in an array features, comprising a base and a plurality of square areas, wherein the light transmittancy of the square areas is different from that of the base, the square areas are arranged on the base with an array arrangement, the photomask has a longitudinal axis, each of the square areas has four edges, and an inclination angle is between one edge of each of the square areas and the longitudinal axis.

6. The photomask of claim 5, wherein the inclination angle is greater than 0 degree and less than 45 degrees.

7. The photomask of claim 5, wherein the square areas have the same sizes.

8. The photomask of claim 5, wherein the square areas are in diamond shapes, and each of the square areas faces its adjacent square areas by corner to corner.

9. The photomask of claim 5, wherein the square areas are light transmissive, and the base is opaque.

10. The photomask of claim 5, wherein the photomask comprises a first square area, a second square area and a third square area, a first gap is between the first square area and the second square area, a second gap is between the first square area and the third square area, and the first gap is different from the second gap.

11. A method for determining a pattern of a photomask, comprising the steps of:
providing a preliminary designed pattern, the preliminary designed pattern comprising a basic portion and a plurality of square portions, wherein the square portions are arranged on the basic portion with an array arrangement, the preliminary designed pattern comprises a first square portion, a second square portion and a third square portion, a first gap is between the first square portion and the second square portion, a second gap is between the first square portion and the third square portion, and the first gap is different from the second gap; and
producing the pattern of the photomask according to the preliminary designed pattern.

12. The method of claim 11, further comprising a step of adjusting the preliminary designed pattern after providing a preliminary designed pattern, wherein the square portions are enlarged to become enlarged square portions by applying global bias, each of the enlarged square portions has a width W₃, P<W₃<\sqrt{2} P, and P represents a pitch between two adjacent square areas.

13. The method of claim 12, wherein four of the enlarged square portions enclose to form an enclosed portion, and the pattern of the photomask corresponds to the enclosed portions.

14. The method of claim 12, wherein each of the enlarged square portions faces its adjacent enlarged square portions by corner to corner.

15. A method for determining a pattern of photomask, comprising:
providing a preliminary designed pattern, the preliminary designed pattern comprising a basic portion, a plurality of square portions and a longitudinal axis, wherein the square portions are arranged on the basic portion with an array arrangement, each of the square portions has four edges, and an inclination angle is between one edge of each of the square portions and the longitudinal axis; and
producing the pattern of the photomask according to the preliminary designed pattern.

16. The method of claim 15, wherein the inclination is greater than 0 degree and less than 45 degrees.

17. The method of claim 15, further comprising a step of adjusting the preliminary designed pattern after providing a preliminary designed pattern, wherein the square portions are enlarged to become enlarged square portions by applying global bias, each of the enlarged square portions has a width W₃, P<W₃<\sqrt{2} P, and P represents a pitch between two adjacent square areas.

18. The method of claim 17, wherein four of the enlarged square portions enclose to form an enclosed portion, and the pattern of the photomask corresponds to the enclosed portions.

19. The method of claim 17, wherein each of the enlarged square portions faces its adjacent enlarged square portions by corner to corner.
